(19) United States
(12) Patent Application Publication
(10) Pub. No.: US 2007/0284703 A1
(43) Pub. Date: Dec. 13, 2007

(54) Semiconductor package structure

(75) Inventors: Kuo-Liang Wu, Hsin-Tien City (TW); Kuo-Shu Iu, Hsin-Tien City (TW); Chih-Wei Chang, Hsin-Tien City (TW)

Correspondence Address: ROSENBERG, KLEIN & LEE, 3458 ELLICOTT CENTER DRIVE-SUITE 101, ELLICOTT CITY, MD, 21043, US

(73) Assignee: LITE-ON SEMICONDUCTOR CORPORATION

(21) Appl. No.: 11/447,989

(22) Filed: Jun. 7, 2006

(51) Int. Cl. H01L 23/495

(52) U.S. Cl. 257/666

(57) ABSTRACT

A semiconductor package structure includes a substrate, a chip module, a lead frame, and a bridging element. The chip module is electrically connected to the substrate. The lead frame is disposed beside one side of the substrate, and the lead frame has a projecting block unit. The bridging element has one side electrically connected with the chip module, and a first positioning unit formed on the other side thereof for electrically retaining with the projecting block unit. Moreover, the semiconductor package structure of the present invention is applied to a design of multi-chip package, and ensures that a bridging element is connected with a chip via the bridging element being retained by a lead frame. In addition, the junction between the bridging element and the lead frame do not cause displacement between the lead frame and the bridging element during the packaging process.

### BACKGROUND OF THE INVENTION

1. Field of The Invention

The present invention relates to a semiconductor package structure, and particularly relates to a semiconductor package structure for increasing the retaining property between a bridging element and a lead frame.

2. Description of the Related Art

Presently, the size of semiconductor chips are becoming smaller and smaller. Consequently, the available interior space of a semiconductor chip is being reduced at a relative rate. Hence, not only is it difficult to design a lead frame for a semiconductor chip, but it is also becoming more difficult to design the chip's bridging element. In general, a bad bridging element will usually cause problems such as the making the semiconductor's electrical property becoming less efficient, making the semiconductor difficult to package, and causing the soldering to be bad. Hence, the above-mentioned problems cause the product yield rate to be reduced and increase costs.

Referring to FIG. 1, a known semiconductor package structure includes a substrate la, a chip 2a, a lead frame 3a, a bridging element 4a, and a support block 5a. The chip 2a is electrically disposed on the substrate 1a, and the lead frame 3a is disposed beside the substrate 1a. In addition, the support block 5a is electrically disposed on the chip 2a for making a top surface of the support block 5a and a top contact point 30a of the lead frame 3a in the same level. Hence, it is easy for the bridging element 4a to be electrically disposed between the support block 5a and the lead frame 3a. In other words, when the bridging element 4a is disposed between the support block 5a and the lead frame 3a, the bridging element 4a is in a parallel status.

However, the known bridging element 4a is difficult to position correctly as the bridging element 4a is easily separated from the lead frame 3a, so that the quality of the known semiconductor package structure is unstable, and its electric and mechanical properties are not easily controlled. Hence, the known semiconductor package structure's yield rate is not easily increased.

### SUMMARY OF THE INVENTION

The present invention provides a semiconductor package structure applied to a design of multi-chip package. The semiconductor package structure of the present invention ensures that because the bridging element is retained by the lead frame the connection between the bridging element and the chip is correct. In addition, the junction between the bridging element and the lead frame does not cause displacement between the lead frame and the bridging element during package process.

Moreover, the present invention has other positive functions such as good positioning, enhancement of the mold locking between the bridging element and the lead frame via the package colloid, fixing the soldering position (the offset and defection of the bridging element are limited), prevention of solder opening and the joint drying (small holes in the lead frame absorb unnecessary solder, and air in the solder can be discharged during soldering). In addition, because the soldering is stable, the forward voltage drop is stable. Hence, the present invention not only reduces power dissipation, but also increases product yield rate and quality.

One aspect of the present invention is a semiconductor package structure. The semiconductor package structure comprises a substrate, a chip module, a lead frame, and a bridging element. The chip module is electrically connected to the substrate. The lead frame is disposed beside one side of the substrate, and the lead frame has a projecting block unit. The bridging element has one side electrically connected with the chip module, and a first positioning unit formed on the other side thereof for electrically retaining with the projecting block unit.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a cross-sectional view of a semiconductor package structure according to a prior art;

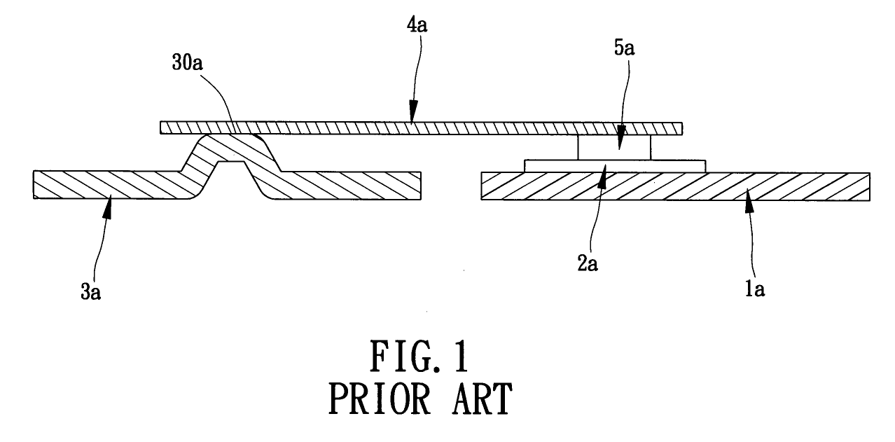

FIG. 2 is a perspective, exploded view of a semiconductor package structure according to a first embodiment of the present invention;

FIG. 3 is a perspective, assembled view of a semiconductor package structure according to a first embodiment of the present invention;

FIG. 4 is a perspective, assembled view of a semiconductor package structure according to a second embodiment of the present invention;

FIG. 5 is a perspective, exploded view of a semiconductor package structure according to a third embodiment of the present invention;

FIG. 6 is a perspective, assembled view of a semiconductor package structure according to a third embodiment of the present invention; and

FIG. 7 is a perspective, assembled view of a semiconductor package structure according to a fourth embodiment of the present invention.

### DETAILED DESCRIPTION OF PREFERRED BEST MOLDS

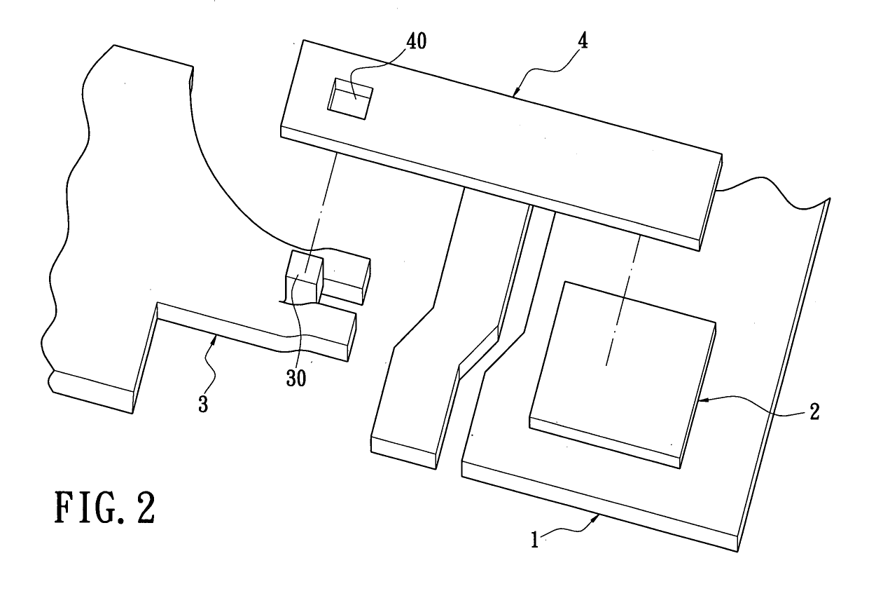

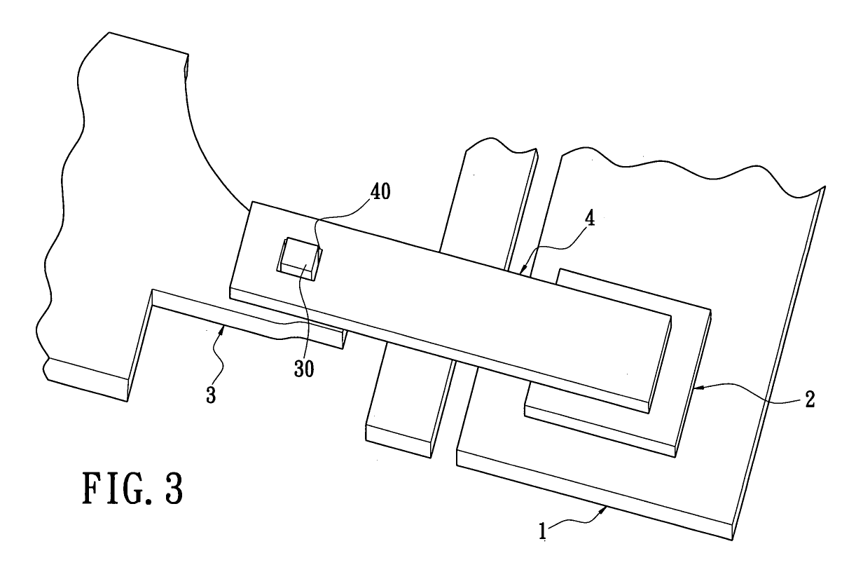

Referring to FIGS. 2-4, a first embodiment of the present invention provides a semiconductor package structure, comprising a substrate 1, a chip module 2, a lead frame 3, and a bridging element 4.

The chip module 2 is electrically connected to the substrate 1, and the chip module 2 can be a multi-chip module. Moreover, the lead frame 3 is disposed beside one side of the substrate 1. The lead frame 3 has a projecting block unit, and the projecting block unit has a projecting block 30. In addition, the bridging element 4 has one side electrically connected with the chip module 2, and the bridging element 4 has a first positioning unit formed on the other side thereof for electrically retaining with the projecting block unit, and the first positioning unit has a positioning through hole 40 correspondingly placed around the projecting block 30.

Moreover, the projecting block 30 can be a circular or rectangular projecting block, and the positioning through hole 40 can be a circular or rectangular positioning through hole corresponding to the circular or rectangular projecting block. However, the above-mentioned shapes of the projecting block 30 and the positioning through hole 40 should not be used to limit the present invention. In other words, both the projecting block 30 and the positioning through hole 40 can be any corresponding shape.

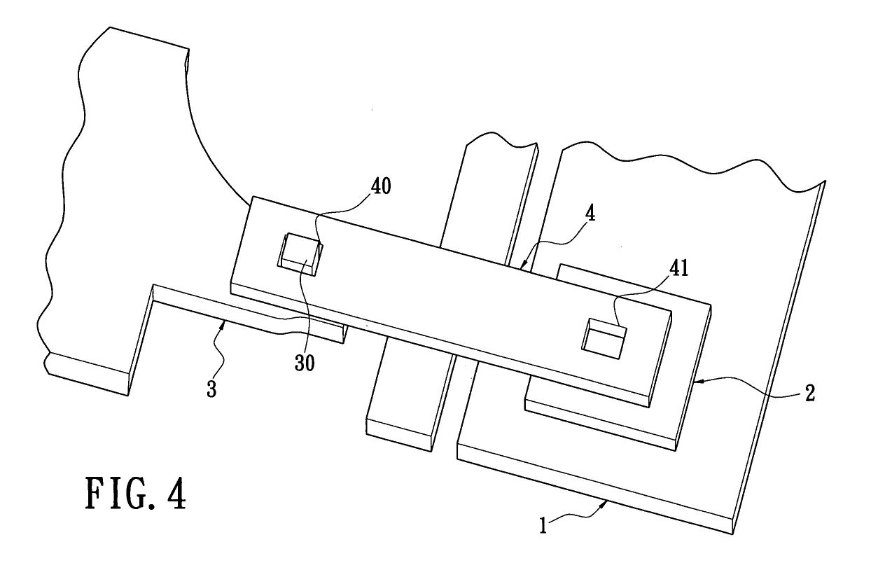

Referring to FIG. 4, a second embodiment of the present invention provides a semiconductor package structure. The difference between the second embodiment and the first embodiment is that in the second embodiment the bridging element 4 further comprises a second positioning unit 41 formed on one side of the bridging element 4, and a shape of the second positioning unit 41 is the same as that of the first positioning unit. Hence, the bridging element 4 can use any of the positioning units (the first positioning unit or the second positioning unit 41) to be placed around the projecting block 30. In other words, because the two positioning units (the first positioning unit or the second positioning unit 41) have the same shape formed on both sides of the bridging element 4 respectively, the bridging element 4 is an idiot-proof device.

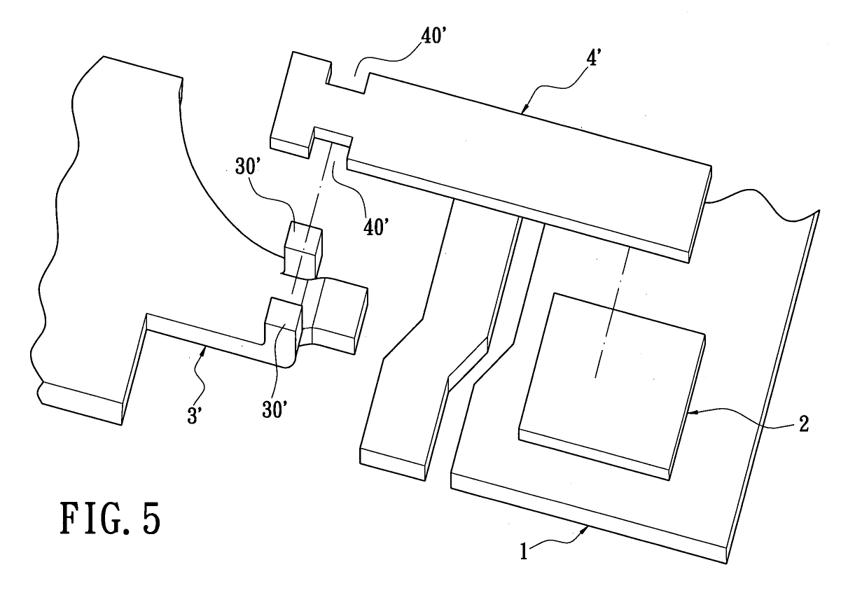

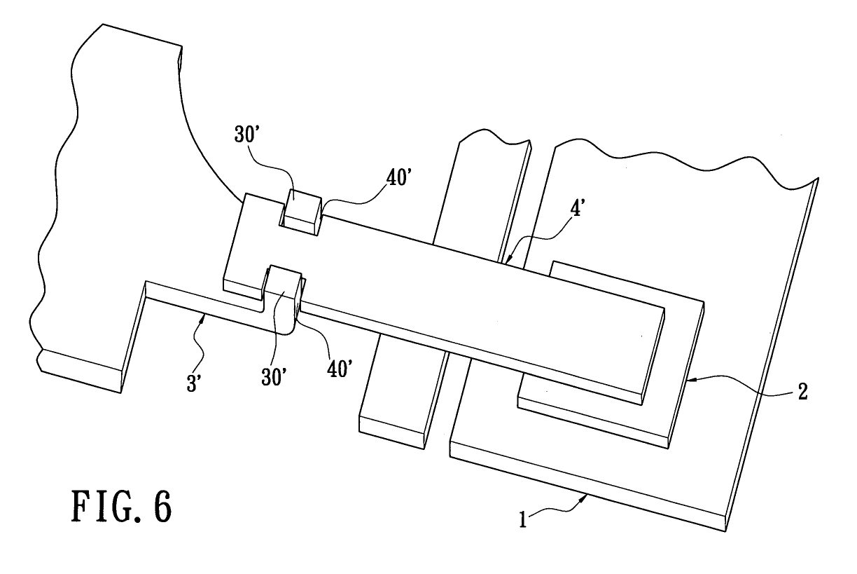

Referring to FIGS. 5-6, a third embodiment of the present invention provides a semiconductor package structure is shown. The difference between the third embodiment and the first embodiment is that the third embodiment of the present invention comprises a lead frame 3′ with a projecting block unit and a bridging element 4′ with a first positioning unit.

Moreover, the projecting block unit includes two projecting blocks 30′, and the first positioning unit includes two positioning concave grooves 40′, penetrating through a lateral side of the bridging element 4′. The two positioning concave grooves 40′ are retained between the two projecting blocks 30′. In addition, each projecting block 30′ can be a circular or rectangular projecting block, and each positioning concave groove 40′ can be a circular or rectangular positioning concave groove corresponding to the circular or rectangular projecting block. However, the above-mentioned shapes of the projecting block 30′ and the positioning concave groove 40′ should not be used to limit the present invention. In other words, both the projecting block 30′ and the positioning concave groove 40′ can be any corresponding shape.

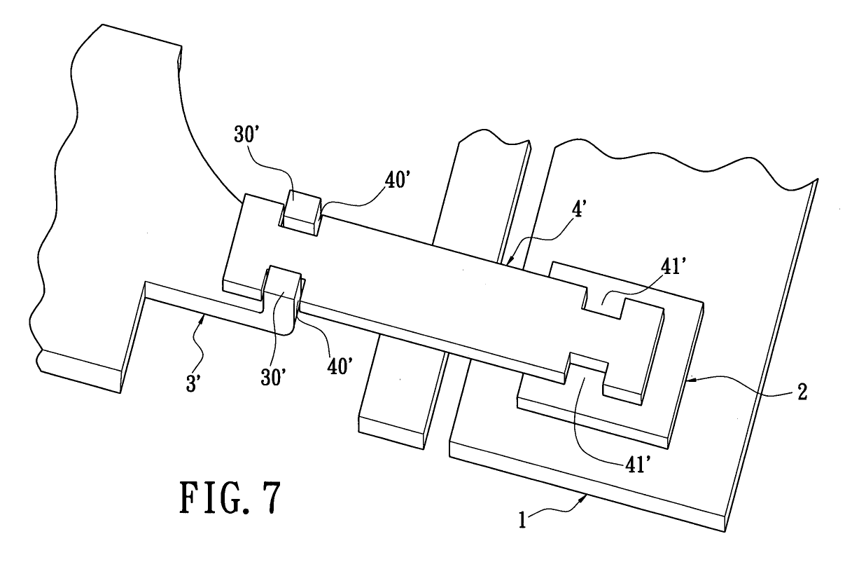

Referring to FIG. 7, a fourth embodiment of the present invention provides a semiconductor package structure. The difference between the fourth embodiment and the third embodiment is in the fourth embodiment the bridging element 4′ further comprises a second positioning unit 41′ formed on the one side of the bridging element 4′ and the shape of the second positioning unit 41′ is the same as that of the first positioning unit. Hence, the bridging element 4′ can use any of the positioning units (the first positioning unit or the second positioning unit 41′) to be placed around the projecting block 30′. In other words, because the two positioning units (the first positioning unit or the second positioning unit 41′) have the same shape formed on both sides of the bridging element 4′ respectively, the bridging element 4′ is an idiot-proof device.

The quantity of the projecting blocks 30 and the positioning through holes 40 should not be used to limit the present invention. In other words, all of the whole retaining methods between the projecting block 30 and the positioning through hole 40 (for example the positioning through hole 40 completely placed around the projecting block 30) are within the scope of the present invention. In addition, the quantity of the projecting blocks 30′ and the positioning concave grooves 40′ should not be used to limit the present invention. In other words, all of the half retaining methods between the projecting block 30′ and the positioning concave groove 40′ (for example the projecting block 30′ has three vertical faces that are closed by the positioning concave groove 40′) are within the scope of the present invention.

In conclusion, the semiconductor package structure of the present invention is applied to a design of multi-chip package. The semiconductor package structure of the present invention ensures that a bridging element is connected with a chip via the bridging element being retained by a lead frame. In addition, the junction between the bridging element and the lead frame does not cause displacement between the lead frame and the bridging element during the packaging process.

Moreover, the present invention has other positive functions such as good positioning, enhancement of the mold locking between the bridging element and the lead frame via the package colloid, fixing the soldering position (the offset and defection of the bridging element are limited), prevention of solder opening and the joint drying (small holes in the lead frame absorb unnecessary solder, and air in the solder can be discharged during soldering). In addition, because the soldering is stable, the forward voltage drop is stable. Hence, the present invention not only reduces power dissipation, but also increases product yield rate and quality.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconductor package structure, comprising:
a substrate;
a chip module electrically connected to the substrate;
a lead frame disposed beside one side of the substrate, wherein the lead frame has a projecting block unit; and
a bridging element having one side electrically connected with the chip module, and a first positioning unit formed on the other side thereof for electrically retaining with the projecting block unit.

2. The semiconductor package structure as claimed in claim 1, wherein the chip module is a multi-chip module.

3. The semiconductor package structure as claimed in claim 1, wherein the projecting block unit has at least one projecting block, and the first positioning unit has at least one positioning through hole correspondingly placed around the at least one projecting block.

4. The semiconductor package structure as claimed in claim 3, wherein the at least one projecting block is a circular or rectangular projecting block, and the at least one positioning through hole is a circular or rectangular positioning through hole corresponding to the circular or rectangular projecting block.

5. The semiconductor package structure as claimed in claim 1, wherein the projecting block unit has at least two projecting blocks, and the first positioning unit has at least two positioning concave grooves penetrated through a lateral side of the bridging element, wherein the two positioning concave grooves are retained between the two projecting blocks.

6. The semiconductor package structure as claimed in claim 5, wherein the projecting block is a circular or rectangular projecting block, and the positioning concave groove is a circular or rectangular positioning concave groove corresponding to the circular or rectangular projecting block.

7. The semiconductor package structure as claimed in claim 1, wherein the bridging element further comprises a second positioning unit formed on the one side thereof, and the second positioning unit has a shape the same as that of the first positioning unit.
